(19) United States
(12) Patent Application Publication
(10) Pub. No.: US 2009/0211785 A1
(43) Pub. Date: Aug. 27, 2009

(54) PRINTED CIRCUIT BOARD WITH EDGE MARKINGS

(76) Inventor: J. Thomas Lovskog, Kavlinge (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 12/034,829

(22) Filed: Feb. 21, 2008

(51) Int. Cl. H05K 1/00

(52) U.S. Cl. 174/250

(57) ABSTRACT

A multilayer printed circuit board may include traces that are printed on selected layers of the board so that the traces extend to the edge of the corresponding layer. When the layers are assembled together, the ends of the traces may be viewable on a side of the printed circuit board. The traces may be arranged to convey information. For example, trace ends may be readable as one or more binary words, as alphanumeric characters or as a bar code.

### TECHNICAL FIELD OF THE INVENTION

The technology of the present disclosure relates generally to printed circuit boards (also referred to as printed wire boards) and, more particularly, to a printed circuit board that includes edge markings.

### BACKGROUND

Many electronic devices, such as mobile telephones, computers, game players and so forth, include a printed circuit board (PCB). The term printed wire board (PWB) is also used to refer to a printed circuit board.

The printed circuit board of an electronic device may retain one or more electrical components (e.g., integrated circuit packages, resistors, capacitors, connectors to off-board components, etc.) and may establish connectivity among the components that are mounted to the printed circuit board. For instance, the printed circuit board may include conductive electrical pathways that connect to the pads, leads and/or contacts the circuit components.

Many printed circuit boards are made in layers. Each layer may include an insulating substrate with conductive traces formed on the top of the substrate and/or the bottom of the substrate. The layers are sandwiched together to form the board. Vias may be used to connect traces that are located on one layer to a trace of another layer.

As the size of electronic devices decrease, the amount of space on the printed circuit board becomes very valuable. In some instances, it may be difficult to find room for all desired components and to mark the board with markings to identify the board. Marking have traditionally been alphanumeric codes or bar codes that have been printed on the top of the board. It is possible to print markings on the bottom or the board, but then the markings may not be accessible after the board has been installed in the electronic device.

### SUMMARY

To improve the manner in which printed circuit boards are marked with identifying information, the present disclosure describes an improved marking technique. In one embodiment, traces are printed on selected layers of the board so that the traces extend to the edge of the layer. When the layers are assembled together, the ends of the traces may be viewable on the edge of the printed circuit board. The traces may be arranged to convey information. For example, trace ends may be readable as one or more binary words. In other embodiments, the trace ends may be arranged as alphanumeric characters or as a bar code.

According to one aspect of the disclosure, a multilayer printed circuit board includes a first insulating layer and a second insulating layer, each layer having an edge that together form a side of the printed circuit board; and a plurality of marking traces located between the first and second layers, and wherein each marking trace has an end located at the edges of the layers, and the marking traces are arranged in a pattern so that the ends of the marking traces form at least part of a pattern on the side of the printed circuit board, the pattern on the side of the printed circuit board conveying information about the printed circuit board.

According to one embodiment of the printed circuit board, the pattern of ends form a binary word.

According to one embodiment of the printed circuit board, the pattern of ends form part of at least one alphanumeric character.

According to one embodiment of the printed circuit board, the pattern of ends form at least part of a bar code.

According to one embodiment of the printed circuit board, the pattern of ends is decipherable by scanning the side of the printed circuit board with an optical reader device.

According to one embodiment of the printed circuit board, the marking traces are connected to a conductive plane that is disposed on the first layer.

According to one embodiment of the printed circuit board, the plane has an inwardly displaced portion to form a space between the edge of the first layer and the plane, the marking traces being located in the space.

According to one embodiment of the printed circuit board, the marking traces are conductive.

According to one embodiment of the printed circuit board, the printed circuit board includes more than two layers and marking traces are located between at least two pairs of layers to form a two dimensional pattern of ends that convey information about the printed circuit board.

According to another aspect of the disclosure, an electronic device includes a housing; electrical circuit components; a multilayer printed circuit board, wherein the electrical circuit components are mounted to the printed circuit board and the printed circuit board is enclosed within the housing, and the printed circuit board including a first insulating layer and a second insulating layer, each layer having an edge that together form a side of the printed circuit board; and a plurality of marking traces located between the first and second layers, and wherein each marking trace has an end located at the edges of the layers, and the marking traces are arranged in a pattern so that the ends of the marking traces form at least part of a pattern on the side of the printed circuit board, the pattern on the side of the printed circuit board conveying information about the printed circuit board.

According to one embodiment of the electronic device, the pattern of ends form a binary word.

According to one embodiment of the electronic device, the pattern of ends form part of at least one alphanumeric character.

According to one embodiment of the electronic device, the pattern of ends form at least part of a bar code.

According to one embodiment of the electronic device, the pattern of ends is decipherable by scanning the side of the printed circuit board with an optical reader device.

According to one embodiment of the electronic device, the marking traces are connected to a conductive plane that is disposed on the first layer.

According to one embodiment of the electronic device, the plane has an inwardly displaced portion to form a space between the edge of the first layer and the plane, the marking traces being located in the space.

According to one embodiment of the electronic device, the printed circuit board includes more than two layers and marking traces are located between at least two pairs of layers to form a two dimensional pattern of ends that convey information about the printed circuit board.

According to one embodiment of the electronic device, the electrical circuit components include communications circuitry that establishes a call over a communications network.

These and further features will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the scope of the appended claims.

Features that are described and/or illustrated with respect to one embodiment may be used in the same way or in a similar way in one or more other embodiments and/or in combination with or instead of the features of the other embodiments.

### BRIEF DESCRIPTION OF THE DRAWINGS

FIG. 1 is a side view of an exemplary printed circuit board that includes edge markings;

FIG. 2 is a schematic view of a mobile telephone as an exemplary electronic device that includes the printed circuit board of FIG. 1;

FIG. 3 is a top view of a first layer of the printed circuit board of FIG. 1;

FIG. 4 is a top view of a second layer of the printed circuit board of FIG. 1;

FIG. 5 is a top view of a third layer of the printed circuit board of FIG. 1;

FIG. 6 is a top view of a fourth layer of the printed circuit board of FIG. 1;

FIG. 7 is a top view of a fifth layer of the printed circuit board of FIG. 1;

FIG. 8 is a top view of a sixth layer of the printed circuit board of FIG. 1; and

FIG. 9 is a top view of a layer of a printed circuit board during a manufacturing process.

### DETAILED DESCRIPTION OF EMBODIMENTS

Embodiments will now be described with reference to the drawings, wherein like reference numerals are used to refer to like elements throughout. It will be understood that the figures are not necessarily to scale.

In the present document, embodiments are described primarily in the context of a printed circuit board for a mobile telephone. It will be appreciated, however, that the exemplary context of a mobile telephone is not the only operational environment in which aspects of the disclosed printed circuit boards and methods of manufacture may be used. Therefore, the circuit boards may be used in connection with any type of appropriate electronic device, examples of which include a mobile telephone, a media player, a gaming device, a computer, a pager, a communicator, an electronic organizer, a personal digital assistant (PDA), a smartphone, a portable communication apparatus, etc.

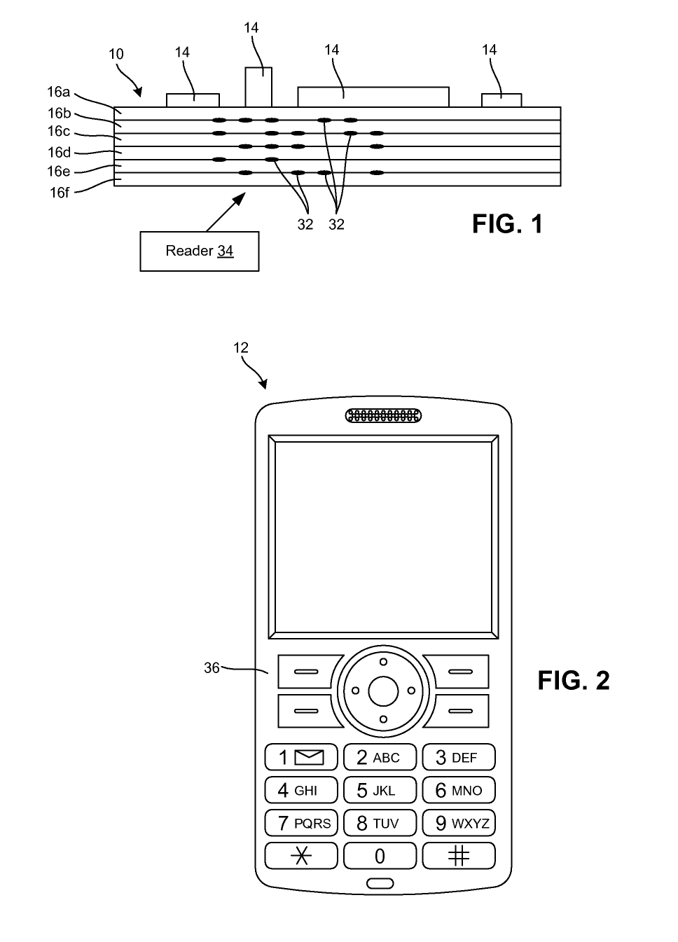

Referring initially to FIGS. 1 and 2, shown in FIG. 1 is a side view a printed circuit board 10 for an electronic device 12 (shown in FIG. 2). The electronic device 12 may be any type of device that has electrical components 14 that are mounted to the printed circuit board 10. The exemplary illustrated electronic device 12 is a mobile telephone that includes communications circuitry, control circuitry, a processor, a memory, audio circuitry, video circuitry, a keypad, a camera, input/output connectors and associated interface circuitry, power supply circuitry, positioning circuitry (e.g., a global positioning service (GPS) receiver and circuit), and so forth. Components 14 that implement these items may be mounted to the printed circuit board 10 and/or have electrical connection to the printed circuit board 10. In the embodiment where the electronic device 12 is a mobile telephone or otherwise includes call making capability, the communications circuitry may be used to establish a call over a communications network.

In the illustrated example, at least some of the electrical components 14 that are mounted to the printed circuit board 10 are integrated circuit packages. The integrated circuit packages may be configured as ball grid arrays (BGAs) that are electrically and mechanically coupled to conductive pads (not shown) of the printed circuit board 10 with solder balls (not shown). Other form factors for the electrical components 14 that are mounted to the printed circuit board 10 are possible. The pads (also referred to as lands) may be coupled to other pads or electrical nodes by conductive traces (not shown) and/or conductive vias (not shown) to establish an electrical pathway from one point of the printed circuit board 10 to another point of the printed circuit board 10.

In the illustrated embodiment, the components 14 are mounted to the top of the printed circuit board 10. It will be appreciated that components 14 may be mounted to the top of the printed circuit board 10, to the bottom of the printed circuit board 10, or to both the top and the bottom of the printed circuit board 10.

The printed circuit board 10 of the illustrated embodiment is a multilayered printed circuit board. As will be appreciated, a multilayered circuit board may be constructed by laminating or stacking insulating layers 16 upon one another. The illustrated printed circuit board has six layers, respectively identified as 16a through 16f.

Conductive structures may be formed on the top and/or bottom of selected layers 16 to form conductive pads, lands, traces, tracks, parts of vias, and conductive planes (e.g., for the establishment of a power plane and/or a ground plane). Thus, the conductive structures may be buried between layers of the printed circuit board 10 as well as on the top and/or bottom of the printed circuit board 10. In one embodiment, the conductive structures may be printed onto each layer 16, although other techniques for adding conductive structures to the layers is known. The conductive structures may be formed from a conductive material, such as copper.

As indicated, conductive vias may traverse one or more layers to establish conductivity between conductive members (e.g., pads, lands, traces, tracks, power planes and ground planes) of the various layers. The conductive vias may be formed by drilling (e.g., laser drilling) or etching through the layers and then filling the resulting aperture. In one construction method, the apertures may be formed in individual layers before the layers are stacked. Once stacked, the previously formed apertures align and the resulting void may be filled or lined with conductive material, such as copper. In another construction method, the layers may be stacked and then the aperture for the via may be formed through one or more layers by drilling or etching.

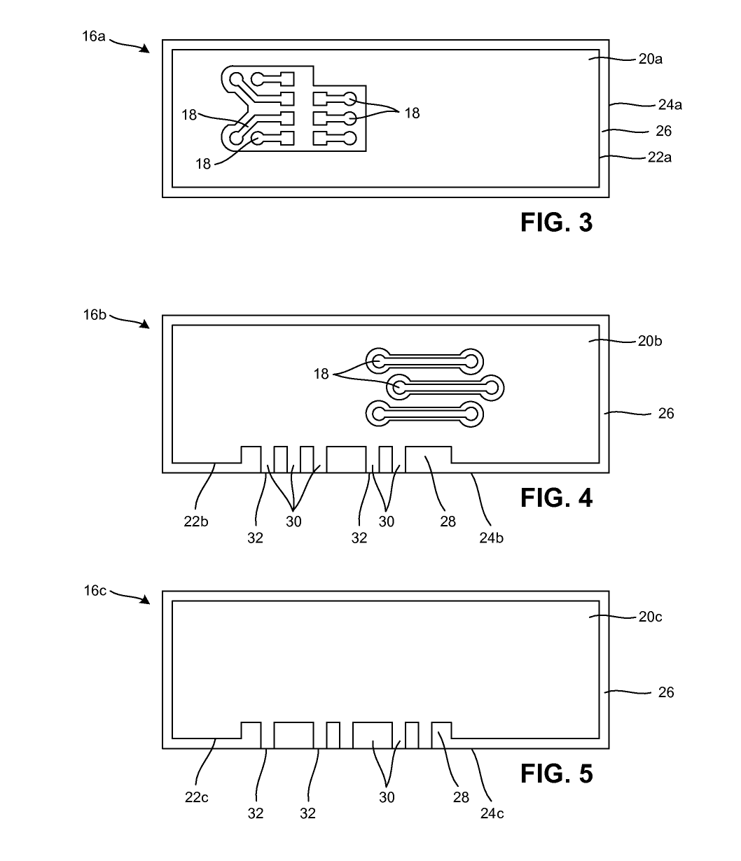

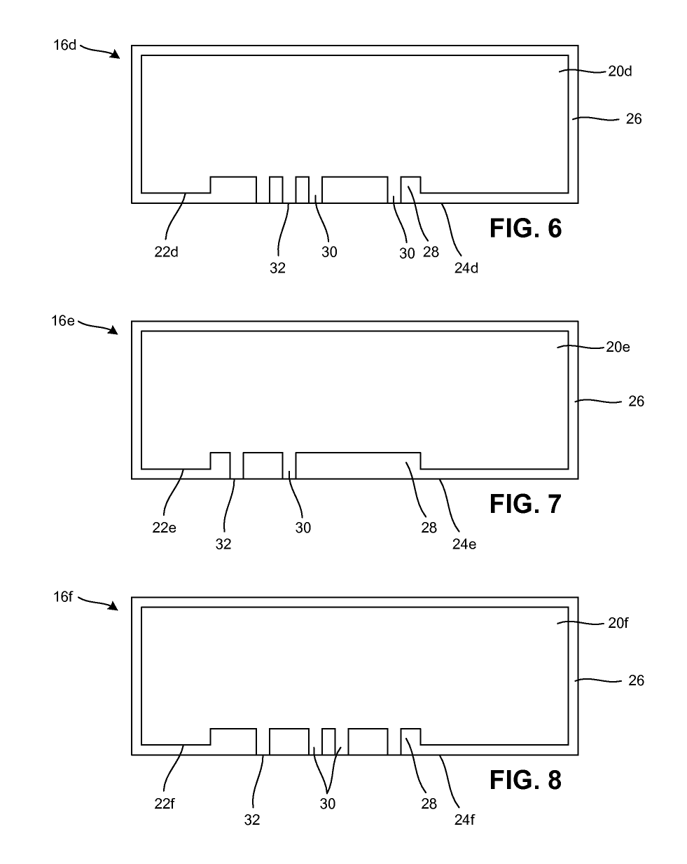

With additional reference to FIGS. 3 through 8, shown are the six exemplary layers 16a through 16f of the illustrated printed circuit board 10. The layers 16 are shown from the top and before the individual layers are stacked and joined together. For simplicity of the drawings, only a few representative conductive structures and vias are shown on the first two layers 16a and 16b. It will be appreciated that the specific layout of structures 18 will depend on the specific printed circuit board.

Some or all of the layers 16 may include a conductive plane 20. The conductive planes 20 may be made from copper, for example. In the illustrated embodiment, the conductive planes 20 are flooded around the structures 18 of each layer. The planes 20 each may have an outside edge 22 that generally follows an edge 24 of the layer 16. The outside edge 22 may be spaced from the edges 24 of the corresponding layer to form a non-conductive boarder 26 along the edge 24 of each layer 16. In other embodiments, portions of the edges 22 of the planes 20 may be laterally even with the edges 24. As will be appreciated, the conductive planes 20 may take other forms. For instance, the plane 18 may be omitted, may not be continuous (e.g., may form multiple planes), may not form a continuous boarder 26 around the edge 24 of the corresponding layer 16, etc.

In the illustrated embodiment, the planes 20b through 20f of the corresponding layers 16b through 16f each have a portion that shifts inward toward an interior area of the layer 16 to form an inwardly displaced portion of the plane 20 to create a space 28 between the plane 20 and the edge 24 of the layer 16 that is wider than the boarder 26. In other embodiments, the space 28 may be omitted.

With continued reference to FIGS. 1 and 3 through 8, one or more of the layers 16 may include marking traces 30 that extend to the edge 24 of the corresponding layer 16 so that an end 32 of the marking trace 30 is visible from the side of the printed circuit board 10. The marking traces 30 may be formed in a pattern on some or all of the layers 16 so that the ends 32 form a corresponding pattern. In the illustrated embodiment, the marking traces 30 are formed in the space 28 between the inwardly displaced portion of the plane 20 and the edge 24 of the layer 16. Also, the marking traces 30 are connected to the plane 20 (e.g., integrally formed with the plane 20). In other embodiments, the marking traces 30 may not be connected to the plane 20, in which case the marking traces 30 may or may not be connected to each other. In other embodiments, the plane 20 may be omitted entirely or may have an omitted section in the area near the marking traces 30. In these embodiments, the marking traces 30 may not be connected to any other conductive structures formed on the layer 16. Alternatively, some or all of the marking traces 30 may be connected to other conductive structures formed on the layer 16.

The pattern of the ends 32 may be arranged so as to have meaning. For instance, in the illustrated embodiment, the presence of an end 32 in a predetermined location may signify a binary “1” and an absence of an end 32 in the predetermined location may signify a binary “0” so that the pattern of ends 32 forms binary (e.g., digital) words. For this purpose, the ends 32 may be arranged in corresponding locations on the side of the printed circuit board 10 so that a meaning may be ascertained from the pattern of the ends 32.

It is noted that the ends 32 of the marking traces 30 may or may not be visible or readily discernable with the unaided eye of a person. In these cases, viewing of a pattern formed by the ends 32 may be aided with an instrument, such as a magnifying glass. In other embodiments, a pattern formed by the ends 32 may be detected and decoded by a reader device 34, such as an optical scanner. The reading device 34 may be able to scan the ends 32 and decipher the meaning of the pattern of the ends 32. In one embodiment, a section of the plane 20 of at least one of the layers 16 may be visible from the side of the printed circuit board 10. The visible plane sections may form a reference for where the pattern of the ends 32 is to be expected. In one embodiment, the visible plane sections may establish a code window on the side of the printed circuit board 10 and provide guidance to the reader 34 as to where the predetermined locations are located relative to the rest of the printed circuit board 10. Alternatively, the predetermined locations may be deduced from detection of the pattern as whole or by the detection of one or more reference markings (e.g., an end 32 that is wider that the rest of the ends 32 or a grouping of ends 32 with a particular arrangement).

In the illustrated embodiment, the pattern of ends 32 form five binary words that are seven bits each when read horizontally. Based on the illustrated arrangement of ends 32, these binary words are set forth in table 1.

TABLE 1

| Bit 6 | Bit 5 | Bit 4 | Bit 3 | Bit 2 | Bit 1 | Bit 0 |
|---|---|---|---|---|---|---|
| 1 | 1 | 1 | 0 | 1 | 1 | 0 |
| 1 | 0 | 1 | 1 | 0 | 1 | 1 |
| 0 | 1 | 1 | 1 | 0 | 0 | 1 |
| 1 | 0 | 1 | 0 | 0 | 0 | 0 |
| 0 | 1 | 0 | 1 | 1 | 0 | 1 |

It is noted that the binary words of table 1 are exemplary. The printed circuit board 10 may have edge markings formed by marking trace ends 32 that combine to form binary words of different values and/or lengths than those shown to convey information regarding the printed circuit board 10. The information may relate to one or more of a model or serial number of the printed circuit board 10, a version number of the printed circuit board 10, a version number of a component 14 that is mounted to the printed circuit board 10, a manufacturing date, a manufacturing site, a manufacturer's identity, and so forth.

In other embodiments, the pattern of the ends 32 may be used to convey information in manner other than using binary words. For instance, the ends 32 may form alphanumeric characters or other symbols. In another embodiment, by varying the width and/or the spacing of the ends 32, the ends 32 may form a bar code or other meaningful arrangement.

In the illustrated embodiment, each of the layers 16b through 16f have marking traces 30. In other embodiments, layers 16 with marking traces 30 may be separated by one or more layers 16 without marking traces 30 to create vertical separation between ends 32 to enhance inspection of the ends 32. In other embodiments, adjacent layers 16 may include the same arrangement of marking traces 30 so that corresponding ends 30 are duplicated to effectively enlarge the aggregate area used to represent a binary value, other symbol or bar code segment.

It will be further appreciated that in the side view of FIG. 1, the thickness of the planes 18 and the ends 32 of the marking traces 30 are shown to be exaggerated relative to the thickness of the layers 16 to aid in illustration of the edge markings formed by the marking traces 30.

With renewed reference to FIG. 2, the printed circuit board 10 may be disposed in the electronic device 12. For example, the printed circuit board 10 may be located within a housing 36 of the electronic device 12. In one embodiment, the printed circuit board may be secured to an interior of the housing using fasteners, such as with screws or with resilient tabs that are integrally formed with the housing 36.

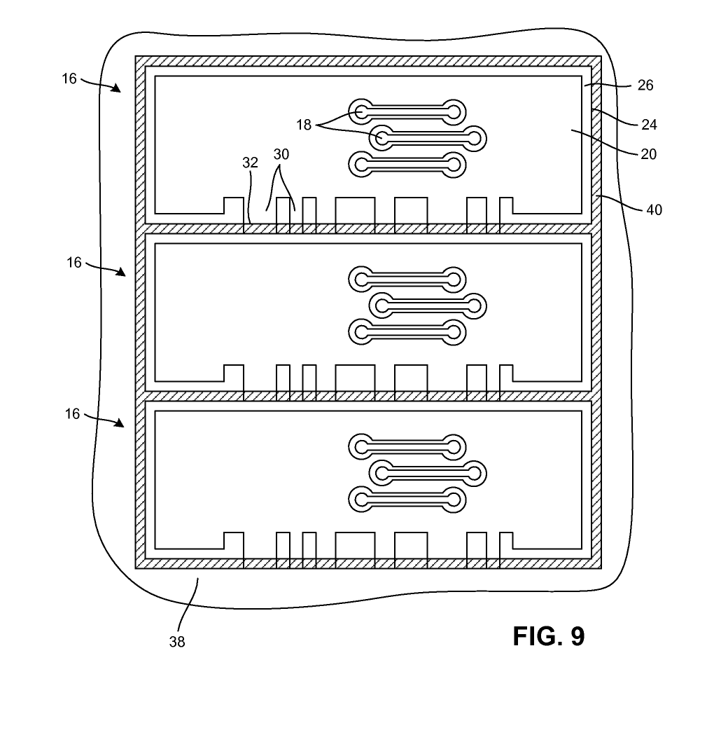

With additional reference to FIG. 9, shown is a representative layer 16 during a manufacturing process of the printed circuit board 10. More specifically, the layer 16 is shown as part of a larger sheet 38, which is partially shown as indicated by the non-uniform edges. The layer 16 is repeated on the sheet 38 to enhance manufacturing efficiencies. The sheet 28 may be laminated together with other sheets having other layers that make up the printed circuit board 10. Similar to the illustrated sheet 28, the layers on the other sheets may be repeated and, when the sheets are stacked, the layers for a single printed circuit board vertically align with one another. The stack of sheets may be cut along cut lines 40 (shown with cross-hatching) to form individual printed circuit boards.

Similar to the layers 16 of FIGS. 3-8, the replicated layer 16 on the sheet 38 may have various structures 18 and the plane 20. The plane 20 may be positioned so that the boarder 26 is present between the future edge 24 and the plane 20 after cutting along the cut lines 40.

The marking traces 30 may extend into the area of the cut lines 40. This allows the marking traces 30 to be cut when the printed circuit boards are cut from the stack of sheets. In this manner, the future ends 32 may be “clean-cut” and flush with the edges 24 after cutting along the cut lines 40. An exemplary cutting technique is to cut the stack of sheets with a cutting tool (not shown), such as a milling machine that uses a milling bit to separate the printed circuit boards from the stack of sheets 38.

The marking traces 30 in the embodiment of FIG. 9 are shown to have a variety of widths and a variety distances between the marking traces 30.

Although certain embodiments have been shown and described, it is understood that equivalents and modifications falling within the scope of the appended claims will occur to others who are skilled in the art upon the reading and understanding of this specification.

What is claimed is:

1. A multilayer printed circuit board, comprising:
a first insulating layer and a second insulating layer, each layer having an edge that together form a side of the printed circuit board; and
a plurality of marking traces located between the first and second layers, and wherein each marking trace has an end located at the edges of the layers, and the marking traces are arranged in a pattern so that the ends of the marking traces form at least part of a pattern on the side of the printed circuit board, the pattern on the side of the printed circuit board conveying information about the printed circuit board.

2. The printed circuit board of claim 1, wherein the pattern of ends form a binary word.

3. The printed circuit board of claim 1, wherein the pattern of ends form part of at least one alphanumeric character.

4. The printed circuit board of claim 1, wherein the pattern of ends form at least part of a bar code.

5. The printed circuit board of claim 1, wherein the pattern of ends is decipherable by scanning the side of the printed circuit board with an optical reader device.

6. The printed circuit board of claim 1, wherein the marking traces are connected to a conductive plane that is disposed on the first layer.

7. The printed circuit board of claim 6, wherein the plane has an inwardly displaced portion to form a space between the edge of the first layer and the plane, the marking traces being located in the space.

8. The printed circuit board of claim 1, wherein the marking traces are conductive.

9. The printed circuit board of claim 1, wherein the printed circuit board includes more than two layers and marking traces are located between at least two pairs of layers to form a two dimensional pattern of ends that convey information about the printed circuit board.

10. An electronic device, comprising:
a housing;
electrical circuit components;
a multilayer printed circuit board, wherein the electrical circuit components are mounted to the printed circuit board and the printed circuit board is enclosed within the housing, and the printed circuit board including:
a first insulating layer and a second insulating layer, each layer having an edge that together form a side of the printed circuit board; and
a plurality of marking traces located between the first and second layers, and wherein each marking trace has an end located at the edges of the layers, and the marking traces are arranged in a pattern so that the ends of the marking traces form at least part of a pattern on the side of the printed circuit board, the pattern on the side of the printed circuit board conveying information about the printed circuit board.

11. The electronic device of claim 10, wherein the pattern of ends form a binary word.

12. The electronic device of claim 10, wherein the pattern of ends form part of at least one alphanumeric character.

13. The electronic device of claim 10, wherein the pattern of ends form at least part of a bar code.

14. The electronic device of claim 10, wherein the pattern of ends is decipherable by scanning the side of the printed circuit board with an optical reader device.

15. The electronic device of claim 10, wherein the marking traces are connected to a conductive plane that is disposed on the first layer.

16. The electronic device of claim 15, wherein the plane has an inwardly displaced portion to form a space between the edge of the first layer and the plane, the marking traces being located in the space.

17. The electronic device of claim 10, wherein the printed circuit board includes more than two layers and marking traces are located between at least two pairs of layers to form a two dimensional pattern of ends that convey information about the printed circuit board.

18. The electronic device of claim 10, wherein the electrical circuit components include communications circuitry that establishes a call over a communications network.
